(19) United States
(12) Patent Application Publication
(10) Pub. No.: US 2014/0212993 A1
(43) Pub. Date: Jul. 31, 2014

(54) METHOD OF MANUFACTURING A MAGNETORESISTIVE DEVICE

(71) Applicants: Sarin A. Deshpande, Chandler, AZ (US); Sanjeev Aggarwal, Scottsdale, AZ (US)

(72) Inventors: Sarin A. Deshpande, Chandler, AZ (US); Sanjeev Aggarwal, Scottsdale, AZ (US)

(73) Assignee: EVERSPIN TECHNOLOGIES, INC., Chandler, AZ (US)

(21) Appl. No.: 14/170,100

(22) Filed: Jan. 31, 2014

Related U.S. Application Data
(60) Provisional application No. 61/759,004, filed on Jan. 31, 2013.

(51) Int. Cl. H01L 43/12

(52) U.S. Cl. CPC H01L 43/12
USPC 438/3

(57) ABSTRACT

A method of manufacturing a magnetoresistive-based device includes etching a hard mask layer, the etching having a selectivity greater than 2:1 and preferably less than 5:1 of the hard mask layer to a photo resist thereover. Optionally, the photo resist is trimmed prior to the etch, and oxygen may be applied during or just subsequent to the trim of the photo resist to increase side shrinkage. An additional step includes an oxygen treatment during the etch to remove polymer from the structure and etch chamber.

This application claims the benefit of U.S. Provisional Application No. 61/759,004 filed 31 Jan. 2013, which is incorporated herein by reference.

### TECHNICAL FIELD

The exemplary embodiments described herein generally relates to methods of manufacturing an integrated circuit device, and more particularly to methods of manufacturing a magnetoresistive-based device, including etching techniques providing smaller structures/bits.

### BACKGROUND

Magnetoelectronic devices, spin electronic devices, and spintronic devices are synonymous terms for devices that make use of effects predominantly caused by electron spin. Magnetoelectronics are used in numerous information devices to provide non-volatile, reliable, radiation resistant, and high-density data storage and retrieval. The numerous magnetoelectronic information devices include, but are not limited to, Magnetoresistive Random Access Memory (MRAM), magnetic sensors, and read/write heads for disk drives.

Typically an MRAM includes an array of magnetoresistive memory elements (bits). Each magnetoresistive memory element typically has a structure that includes multiple magnetic layers separated by various non-magnetic layers, such as a magnetic tunnel junction (MTJ), and exhibits an electrical resistance that depends on the magnetic state of the device. Information is stored as directions of magnetization vectors in the magnetic layers. Magnetization vectors in one magnetic layer are magnetically fixed or pinned, while the magnetization direction of another magnetic layer may be free to switch between the same and opposite directions that are called “parallel” and “antiparallel” states, respectively. Corresponding to the parallel and antiparallel magnetic states, the magnetic memory element has low and high electrical resistance states, respectively. Accordingly, a detection of the resistance allows a magnetoresistive memory element, such as an MTJ device, to provide information stored in the magnetic memory element. There are two completely different methods used to program the free layer: field switching and spin-torque switching. In field-switched MRAM, current carrying lines adjacent to the MTJ bit are used to generate magnetic fields that act on the free layer. In spin-torque MRAM, switching is accomplished with a current pulse through the MTJ itself. The angular momentum carried by the spin-polarized tunneling current causes reversal of the free layer, with the final state (parallel or antiparallel) determined by the polarity of the current pulse. Spin-torque transfer is known to occur in MTJ devices and giant magnetoresistance devices that are patterned or otherwise arranged so that the current flows substantially perpendicular to the interfaces, and in simple wire-like structures when the current flows substantially perpendicular to a domain wall. Any such structure that exhibits magnetoresistance has the potential to be a spin-torque magnetoresistive memory element. In some device designs the free magnetic layer of the MTJ may have stable magnetic states with magnetization in the film plane, and in other cases the stable states have magnetization perpendicular to the plane. In-plane devices typically have their magnetic easy axis defined by the in-plane shape of the free layer and perpendicular devices typically employ materials with a perpendicular magnetic anisotropy (PMA) that create a perpendicular easy axis.

Bit pattern fidelity is extremely important for MRAM performance. An MTJ bit etch comprises a top electrode etch (primarily chemical) and a magnetic stack etch (primarily physical). A hard mask of photoresist and tetra-ethyl-ortho-silane (TEOS) does not perform well under these two etches. The bit shape is changed during the top electrode etch and loses its pattern fidelity. This change in bit shape may be reduced by the use of a thick photoresist for high aspect ratio bits, but the thick photoresist has a tendency to collapse causing irregular bit shape.

Accordingly, there is a need for a method of manufacturing a magnetoresistive-based device having a hard mask that provides high bit pattern fidelity. Furthermore, other desirable features and characteristics of the exemplary embodiments will become apparent from the subsequent detailed description and the appended claims, taken in conjunction with the accompanying drawings and the foregoing technical field and background.

### BRIEF SUMMARY

A method of manufacturing a magnetoresistive-based device provides high bit pattern fidelity by providing structures having a high aspect ratio and high pattern fidelity.

In an exemplary embodiment, a method of manufacturing a magnetoresistive-based device includes providing a magnetic material layer; depositing an electrical conductive layer over the magnetic material layer; depositing a hard mask layer over the metal layer; depositing a patterned photo resist over the dielectric layer; etching the hard mask layer not covered by the photo resist with a selectivity consisting of at least 2:1 or greater of the electrical conductive layer to the photo resist to form a hard mask; etching the electrical conductive layer not covered by the hard mask to form an electrode; and etching the magnetic material layer not covered by the electrode to form a magnetic material stack.

In another exemplary embodiment, a method of manufacturing a magnetoresistive-based device includes an electrical conductive layer formed over a magnetic material layer, a hard mask layer formed over the electrical conductive layer, and a patterned photo resist formed over the hard mask layer, the method comprising etching the hard mask layer not covered by the patterned photo resist with a selectivity of at least 2:1 to form a hard mask; etching the electrical conductive layer not covered by the hard mask to form an electrode; and etching the magnetic material layer not covered by the electrically conductive electrode to form a magnetic material stack.

### BRIEF DESCRIPTION OF THE DRAWINGS

The present invention will hereinafter be described in conjunction with the following drawing figures, wherein like numerals denote like elements, and

FIGS. 1-6 are cross sectional views of the manufacture of a magnetoresistive-based device in accordance with a first exemplary embodiment;

FIG. 7 is a flow chart of a method of manufacturing a magnetoresistive-based device in accordance with a first exemplary embodiment; and

FIG. 8 is a flow chart of a method of manufacturing a magnetoresistive-based device in accordance with a second exemplary embodiment.

### DETAILED DESCRIPTION

The following detailed description is merely illustrative in nature and is not intended to limit the embodiments of the subject matter or the application and uses of such embodiments. Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

During the course of this description, like numbers are used to identify like elements according to the different figures that illustrate the various exemplary embodiments.

The exemplary embodiments described herein may be fabricated using known lithographic processes as follows. The fabrication of integrated circuits involves the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes. For example, a layer of photo resist material is applied onto a layer overlying a wafer substrate. A photo mask (containing clear and opaque areas) is used to selectively expose this photo resist material by a form of radiation, such as ultraviolet light, electrons, or x-rays. Either the photo resist material exposed to the radiation, or that not exposed to the radiation, is removed by the application of a developer. An etch may then be applied to the layer not protected by the remaining resist, and when the resist is removed, the layer overlying the substrate is patterned. Alternatively, an additive process could also be used, e.g., building a structure using the photo resist as a template.

With reference to FIG. 1, a cross-sectional view of a partially formed magnetoresistive-based device 100 includes an electrically conductive layer 102, a tunnel barrier layer 104, magnetic layers 106, an electrically conductive layer 108, a hard mask layer 110, and a photo resist layer 112.

The electrically conductive layer 102 comprising one or more layers of electrically conductive materials (for example, Tantalum (Ta), Tantalum-Nitride (TaN) or Ta—TaN composite) may be etched, formed and/or patterned using any etchants and/or technique now known or later developed—for example, using mechanical etchants and techniques (for example, sputter etchants and techniques) or chemical etching techniques. It should be noted that the present inventions may employ any suitable etchants and techniques (for example, CF4, CHF3, CH2F2 in combination with inert carrier gases such as Ar or Xe), whether now known or later developed, to etch the one or more layers of electrically conductive materials and thereby form, define and/or provide the electrode 102′. Notably, in one embodiment, a Ta, TaN or Ta—TaN composite electrode 102′ may include a thickness of about 50-1000 Angstroms. The electrode 102′ may include pinning and pinned ferromagnetic layers (not show) as known to those in the art, and may be a material, for example, iridium manganese, platinum manganese, cobalt iron, cobalt iron boron, nickel iron, ruthenium, and the like, or any combination thereof.

The tunnel barrier layer 104 may be an insulating material in one exemplary embodiment, for example, aluminum oxide or magnesium oxide.

The magnetic layers 106 includes, for example and as known to those in the industry, one or more synthetic antiferromagnetic structures (SAF) or synthetic ferromagnetic structures (SYF) for example, nickel iron, cobalt iron, cobalt iron boron, ruthenium, and/or the like, one or more layers of magnetic materials (for example, Nickel (Ni), Iron (Fe), Cobalt (Co), Palladium (Pd), Magnesium (Mg), Manganese (Mn) and alloys thereof), and other materials (including non-magnetic (for example, Ruthenium (Ru), Copper (Cu), Aluminum (Al)) now known or later developed. Such materials and/or structures may be arranged in any combination or permutation now known or later developed

The hard mask layer 110 (metal layer) is deposited, grown, sputtered and/or provided (hereinafter collectively “deposited” or forms thereof) on one or more layers of electrically conductive materials using any technique now known or later developed, for example, well known conventional techniques. In one embodiment, the hard mask layer 110 includes and/or consists of a material that is relatively inert to or during the etch process of the electrical conductive electrode 108 and the magnetic layers 106. For example, in one embodiment, the hard mask layer 110 includes and/or consists of material having a selectivity in connection with the chemical etch and/or mechanical etch processes of the one or more layers of electrically conductive materials and/or magnetic materials that is greater than or equal to 10:1 and, in a preferred embodiment, includes a selectivity that is greater than or equal to 20:1.

In a preferred embodiment, the hard mask layer 110 may be a combination of a silicon oxide (for example, provided using tetraethylorthosilicate (TEOS)) and aluminum, magnesium, titanium, tantalum, or any combination thereof. In this embodiment, after deposition of the aluminum, magnesium, titanium, tantalum, or any combination thereof, the silicon oxide is deposited, for example using TEOS whereby oxygen is absorbed by the aluminum, magnesium, titanium, tantalum, or any combination thereof to from an aluminum oxide, magnesium oxide, titanium oxide, tantalum oxide, or any combination thereof, respectively, layer beneath the silicon oxide. This material may be useful in “protecting” the side walls of the magnetic materials of the MTJ device 100 and/or exposed surfaces or edges of the tunnel barrier 104 during subsequent processing to form the MTJ device 100. As noted above, the techniques described in U.S. Pat. No. 8,119,424 may be employed to improve, maintain and/or enhance the integrity and/or uniformity of the physical and/or electrical characteristics of the magnetic materials of the MTJ device 100 in light of subsequent processing (for example, the etching processes to form the second portion 105 of the MTJ device 100).

The hard mask layer 110 may include and/or consist of one or more noble metals and/or alloy thereof, for example, alloys of a noble metal with transition metals (for example, Pt, Ir, Mo, W, Ru and/or alloy AB (where A=Pt, Ir, Mo, W, Ru and B=Fe, Ni, Mn). Further, in one embodiment, the hard mask layer 110 may include a thickness in the range of about 5-200 Angstroms, and in a preferred embodiment, in the range of about 10-150 Angstroms, and more preferred embodiment, in the range of about 20-100 Angstroms. For example, the hard mask 110 may comprise PtMn or IrMn and include a thickness range of, for example, 15-150 Angstroms or 25-100 Angstroms.

In one embodiment, the hard mask layer 110 includes one or more noble metals and/or alloys thereof, for example, alloys of a noble metal with transition metals (for example, Pt, Ir, Mo, W, Ru and/or alloy AB (where A=Pt, Ir, Mo, W, Ru and B=Fe, Ni, Mn). In addition, in one embodiment, the metal hard mask includes a thickness range of about 5-200 Angstroms, and in a preferred embodiment, of about 10-200 Angstroms, and a more preferred embodiment, of about 20-100 Angstroms. For example, the metal mask may be comprised of PtMn or IrMn and include a thickness range of, for example, 15-150 Angstroms or 20-100 Angstroms.

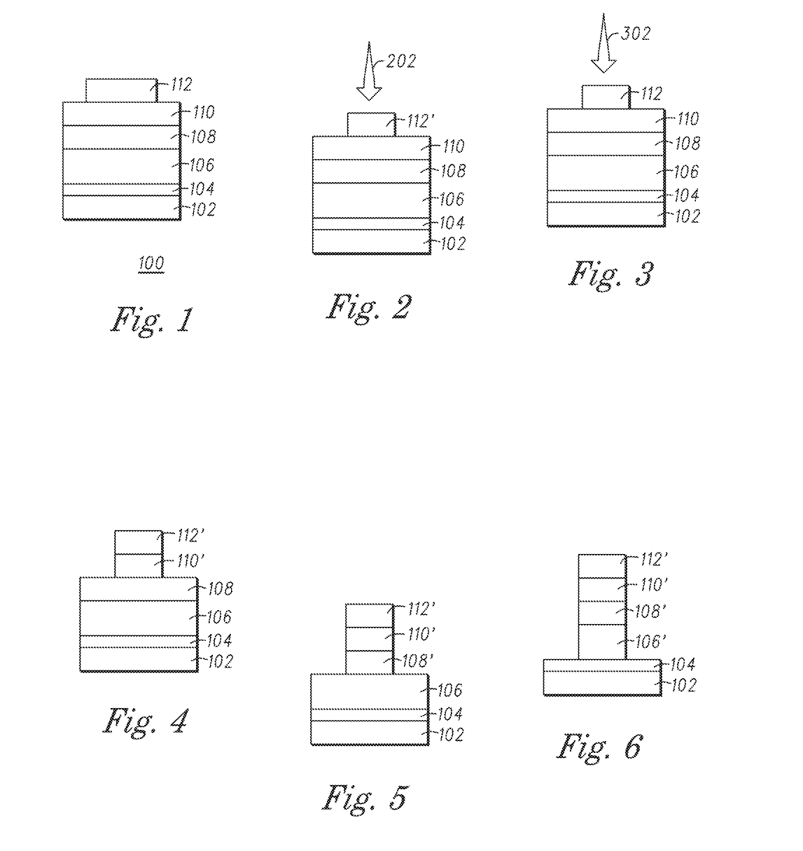

The photo resist layer 112 is deposited on the hard mask layer 110 and patterned to predetermined dimensions consistent with or correlated to selected dimensions of the electrically conductive electrode to be formed (FIG. 2). The photo resist layer 112 may be deposited and patterned using any technique now known or later developed, for example, 248 nm or 193 nm (dry and immersion) well known conventional deposition and lithographic techniques, including photosensitive poly(phenylene ether ketone) (PEK), ultraviolet (UV) and other deep ultraviolet (DUV) and photo resists having a wavelength of 365 nm (i-line).

In one aspect, the present inventions relate to, among other things, methods of manufacturing structures having high aspect ratio and high pattern fidelity, for example, MTJ bits or structures fabricated in or on integrated circuits (for example, high density MRAM—whether discrete or embedded). The methods and processes described herein may include a suitable selectivity (hardmask vs. photo resist) which enables use of a thinner photo resist layer (which facilitates fabrication of smaller bits/structures) and also presents a method for obtaining additional trim during a hard mask etch.

In one exemplary embodiment, the etch process of the present inventions may be implemented in a dielectric etch chamber to selectively etch the hard mask (for example, SiO₂) compared to the photo resist. In a preferred embodiment, a process according to the present inventions may yield a selectivity of 2:1 to 5:1 (SiO₂:photo resist) using the preferred range of process parameters described herein. A higher selectivity greater than 5:1 may be used.

In another exemplary embodiment, the process is performed in a magnetically enhanced plasma etch chamber wherein the magnetic field of a magnetically enhanced plasma maintains, contains, and/or restricts the plasma to a particular region (for example, over the wafer). In this way, etchant ions in the plasma may be contained or maintained to a region thereby providing a more uniform etch and/or higher selectivity etch rates.

Referring to FIG. 2, after initially patterning the photo resist layer 112, the photoresist layer 112 is trimmed (to form the photo resist 112′) to adjust or shrink the size of at least a portion of the MTJ device 100 which is formed, defined and/or patterned using the hard mask 110. The trimming process may also provide pattern fidelity (uniform edges of the bit) in addition to increasing the aspect ratio and smoothness. The photo resist layer 112 may be trimmed using any technique now known or later developed, for example, well known conventional trimming techniques. In one embodiment, a trim process may employ O₂ or Cl₂/O₂ (1:1) or CF₄/O₂ (1:1) gases 202 to shrink the photo resist 112′. It may be advantageous to adjust the ratio of the gases 202 and process time to obtain the desired size. Notably, other gases 202 may be substituted for Cl₂ and CF₄ such as CHF₃, CH₂F₂, etc.

The processes of the exemplary embodiments, when used to manufacture magnetic memories, enables use of a thinner photoresist 112′ and/or longer trim resulting in smaller bits with the dielectric layer intact to make good contact to the MTJ bit. Note that the process may be used in integrated circuit manufacture other than that of magnetic memories.

Optionally, during and/or after the photo resist layer 112 is trimmed, a gas 302 may be applied (FIG. 3) to treat the photo resist 112′ for the purpose of removing any polymer generated during the etch process, thereby preventing build-up in the chamber and/or on the magnetoresistive-based device 100 being etched. This gas 302 may be, preferably oxygen, but may include inert carrier gases such as Ar with Cl₂, HCl, HBr, Br₂, BCl₃, CF₄, or CHF₃. When applied during the trim (FIG. 2), additional trim is achieved. This application of a gas 302 results in a decrease of the bit size as the oxygen content is increased when a plasma etch chamber is used. The gas 302 hardens the photo resist 112′, thereby enhancing the resistance to subsequent etch chemistries and enhancing the photo resist selectivity. Furthermore, the resulting enhancement of the resistance to the subsequent etch chemistries stabilizes the edges of the bits with respect to rounding and breaking/falling which improves pattern fidelity.

With reference to FIG. 4, the hard mask layer 110 is then etched to form the hard mask 110′, for example, via mechanical etching (such as, for example, via sputter etching techniques) having a selective of greater than 2:1, but preferably 2:1 to 5:1 of the hard mask 110′ to the photo resist 112′, to form or provide the hard mask 110′. Notably, the hard mask layer 110 may be etched, formed and/or patterned using any etchants and/or technique now known or later developed—for example, using conventional etchants and techniques (for example, optical image end point techniques). It should be noted that the present inventions may employ any suitable materials, e.g., metal or a dielectric, and techniques, whether now known or later developed, to etch the hard mask layer 110 and thereby form, define and/or provide the hard mask 110′.

With reference to FIG. 5, the one or more layers of electrically conductive materials 108 are then etched with the hard mask 110′, thereby protecting certain portions thereof, to form, define, pattern and/or provide the electrode 108′. The one or more layers of electrically conductive materials 108 (for example, Ta or Ta—TaN composite) may be etched, formed and/or patterned using any etchants and/or technique now known or later developed—for example, using mechanical etchants and techniques (for example, sputter etchants and techniques). It should be noted that the present inventions may employ any suitable etchants and techniques, whether now known or later developed, to etch the one or more layers of electrically conductive materials and thereby form, define and/or provide the electrode 108′.

After etching the one or more layers of electrically conductive materials 108 and using the hard mask 110′ to protect the electrode 108′, the one or more layers of magnetic materials 106 are etched to form, define, pattern and/or provide the magnetic stack 106′ (FIG. 6). The one or more layers of magnetic materials 106 may be etched, formed, and/or patterned using any etchants and/or technique now known or later developed—for example, using mechanical and/or chemical techniques (for example, a low bias power sputter technique or a chemical etch technique such as a conventional fluorine and/or chlorine based etch technique). Notably, the hard mask 110′ and electrode 108′ are relatively unaffected during formation, definition and/or patterning the magnetic stack 106′. Here, the hard mask 110′ is relatively inert to such processing and the hard mask 110′ protects the electrode 108′ (for example, particularly where such processing employs a mechanical etch technique—such as, low bias power sputter etch technique, due to the metal hard mask's sputter yield at those energies employed in connection with low bias power sputter etch technique. Note the photoresist 112′ may be removed to facilitate electrical connection to the electrode 110′.

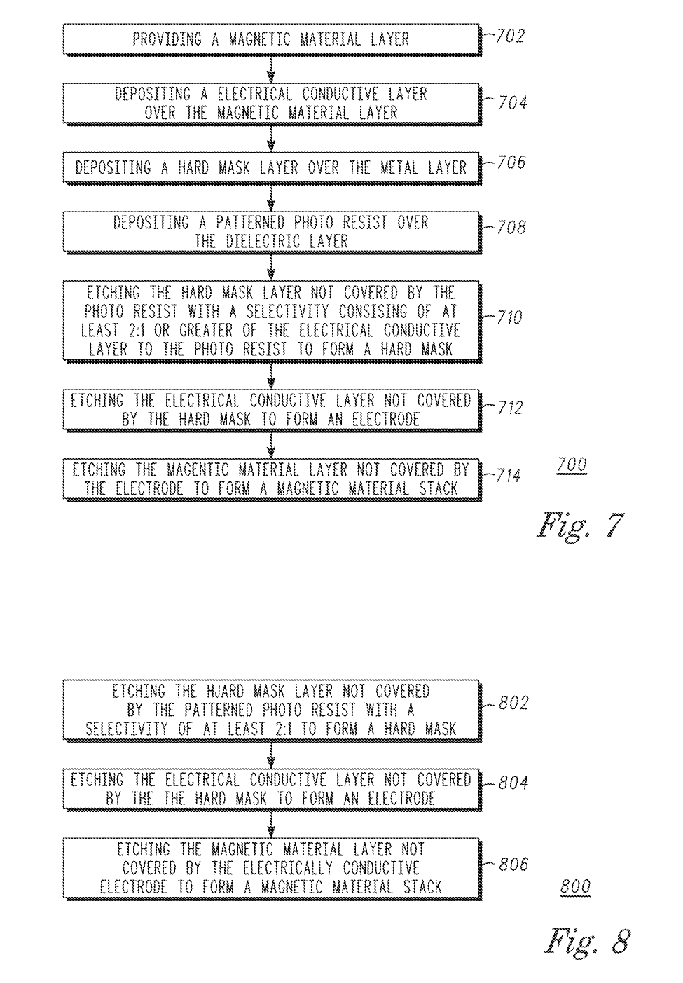

In one embodiment, after formation, definition and/or patterning of the magnetic stack 106′, the hard mask 110 may be removed or stripped to facilitate electrical contact to the exposed electrically conductive electrode 504 (FIG. 7). The hard mask 110 may be removed or stripped using, for example, conventional techniques. Indeed, after removing or stripping the hard mask 110, the exposed electrically conductive electrode 108 may be connected to sense, read and/or write conductors (not shown) and the magnetoresistive-based device completed using any processes and/or structures now known or later developed. Notably, in another embodiment, the hard mask 110 is not removed or stripped but the magnetoresistive-based device is completed as described immediately above.

Notably, in another embodiment, the hard mask 110, after formation, definition and/or patterning of the magnetic material stack, may be retained on or over the magnetic material stack and thereafter employed as the electrically conductive electrode (or a portion thereto). That is, after formation, definition and/or patterning of the electrically conductive electrode via etching of one or more layers of electrically conductive materials, the metal hard mask is not removed but employed as the electrically conductive electrode (or portion thereof). In this embodiment, the material of the metal hard mask is sufficiently conductive to function as an electrically conductive electrode as well as sufficiently selective in connection with the etch processes (for example, chemical etch and/or mechanical etch processes) of the one or more the layers of magnetic materials which form or define the magnetic material stack of the magnetoresistive-based device. For example, in one embodiment, the metal hard mask may be PtMn and/or IrMn—which are (i) electrically conductive alloys and (ii) relatively resistant to those certain etch processes of one or more layers of magnetic materials (for example, conventional fluorine and/or chlorine based etch processes) that form, define, and/or provide the magnetic material stack materials of the magnetoresistive-based device.

FIGS. 7 and 8 are flow charts that illustrate exemplary embodiments of methods 700, 800 for manufacturing a magnetoresistive-based device. For illustrative purposes, the following description of methods 700, 800 may refer to elements mentioned above in connection with FIGS. 1-6. It should be appreciated that methods 700, 800 may include any number of additional or alternative tasks, the tasks shown in FIGS. 7-xxx need not be performed in the illustrated order, and methods 700, 800 may be incorporated into a more comprehensive procedure or process having additional functionality not described in detail herein. Moreover, one or more of the tasks shown in FIGS. 7-8 could be omitted from an embodiment of the methods 700, 800 as long as the intended overall functionality remains intact.

Referring to the flow chart of FIG. 7, a first exemplary embodiment of manufacturing a magnetoresistive-based device includes providing 702 a magnetic material layer; depositing 704 an electrical conductive layer over the magnetic material layer; depositing 706 a hard mask layer over the metal layer; depositing 708 a patterned photo resist over the dielectric layer; etching 710 the hard mask layer not covered by the photo resist with a selectivity consisting of at least 2:1 or greater of the electrical conductive layer to the photo resist to form a hard mask; etching 712 the electrical conductive layer not covered by the hard mask to form an electrode; and etching 714 the magnetic material layer not covered by the electrode to form a magnetic material stack.

Referring to the flow chart of FIG. 8, a second exemplary embodiment of manufacturing a magnetoresistive-based device, including an electrical conductive layer formed over a magnetic material layer, a hard mask layer formed over the electrical conductive layer, and a patterned photo resist formed over the hard mask layer, comprises etching the hard mask layer not covered by the patterned photo resist with a selectivity of at least 2:1 to form a hard mask; etching the electrical conductive layer not covered by the hard mask to form an electrode; and etching the magnetic material layer not covered by the electrically conductive electrode to form a magnetic material stack.

The bit shape of the exemplary embodiments is retained from the photoresist patterning through etch by the use of a thin metal hard mask, allowing for a thinner photoresist and thereby improving the required resist aspect ratio for a high aspect ratio top electrode height to critical dimension (CD) ratios. Pattern collapse during photoresist or during etch caused by a large photoresist thickness is eliminated, thereby improving on photo fidelity.

There are many inventions described and illustrated herein. While certain embodiments, features, attributes and advantages of the inventions have been described and illustrated, it should be understood that many others, as well as different and/or similar embodiments, features, attributes and advantages of the present inventions, are apparent from the description and illustrations. As such, the above embodiments of the inventions are merely exemplary. They are not intended to be exhaustive or to limit the inventions to the precise forms, techniques, materials and/or configurations disclosed. Many modifications and variations are possible in light of this disclosure. It is to be understood that other embodiments may be utilized and operational changes may be made without departing from the scope of the present inventions. As such, the scope of the inventions is not limited solely to the description above because the description of the above embodiments has been presented for the purposes of illustration and description.

Importantly, the present inventions are neither limited to any single aspect nor embodiment, nor to any combinations and/or permutations of such aspects and/or embodiments. Moreover, each of the aspects of the present inventions, and/or embodiments thereof, may be employed alone or in combination with one or more of the other aspects and/or embodiments thereof. For the sake of brevity, many of those permutations and combinations will not be discussed and/or illustrated separately herein.

Although the described exemplary embodiments disclosed herein are directed to various memory or sensor structures and methods for making same, the present invention is not necessarily limited to the exemplary embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. Moreover, the thickness of the described layers may deviate from the disclosed thickness values. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

What is claimed is:

1. A method of manufacturing a magnetoresistive-based device, comprising:
providing a magnetic material layer;
depositing a electrical conductive layer over the magnetic material layer;
depositing a hard mask layer over the metal layer;
depositing a patterned photo resist over the dielectric layer;
etching the hard mask layer not covered by the photo resist with a selectivity consisting of at least 2:1 or greater of the electrical conductive layer to the photo resist to form a hard mask;
etching the electrical conductive layer not covered by the hard mask to form an electrode; and
etching the magnetic material layer not covered by the electrode to form a magnetic material stack.

2. The method of claim 1 further comprising:
treating the photo resist with a polymer generating gas prior to etching the dielectric layer to form a polymer over the surface of the photo resist to harden the photoresist and make it resistant to subsequent etch chemistries.

3. The method of claim 1 further comprising:
trimming the photo resist prior to etching the dielectric layer.

4. The method of claim 1 wherein the etching the dielectric layer comprises:
etching in a magnetic enhanced plasma to focus the plasma over the magnetoresistive-based device.

5. The method of claim 1 wherein the etching the dielectric layer comprises:
etching in a dielectric etch chamber.

6. The method of claim 1 wherein the selectivity consists of a value within the range consisting of 2:1 to 5:1.

7. The method of claim 1 wherein the selectivity consists of a value greater than 5:1.

8. The method of claim 1 wherein depositing the metal layer comprises:
depositing the metal layer consisting of one or more noble metals, or one or more noble metals and alloys thereof.

9. The method of claim 1 wherein depositing the metal hard mask comprises:
depositing the metal hard mask consisting of at least one of PtMn and IrMn

10. The method of claim 1 wherein depositing the metal hard mask comprises:
depositing the metal hard mask comprising at least one of the elements selected from the group consisting of Pt, Ir, Mo, W, Ru and alloy AB (where A comprises Pt, Ir, Mo, W, Ru and B comprises Fe, Ni, Mn).

11. A method of manufacturing a magnetoresistive-based device, including an electrical conductive layer formed over a magnetic material layer, a hard mask layer formed over the electrical conductive layer, and a patterned photo resist formed over the hard mask layer, the method comprising:
etching the hard mask layer not covered by the patterned photo resist with a selectivity of at least 2:1 to form a hard mask;
etching the electrical conductive layer not covered by the hard mask to form an electrode; and
etching the magnetic material layer not covered by the electrically conductive electrode to form a magnetic material stack.

12. The method of claim 11 further comprising:
treating the photo resist with a polymer generating gas prior to etching the dielectric layer to form a polymer over the surface of the photo resist to harden the photoresist and make it resistant to subsequent etch chemistries.

13. The method of claim 11 further comprising:
trimming the photo resist prior to etching the dielectric layer.

14. The method of claim 11 wherein the etching the dielectric layer comprises:
etching in a magnetic enhanced plasma to focus the plasma over the magnetoresistive-based device.

15. The method of claim 11 wherein the etching the dielectric layer comprises:
etching in a dielectric etch chamber.

16. The method of claim 11 wherein the selectivity consists of a value within the range consisting of 2:1 to 5:1.

17. The method of claim 11 wherein the selectivity consists of a value greater than 5:1.

18. The method of claim 11 wherein depositing the metal layer comprises:
depositing the metal layer consisting of one or more noble metals, or one or more noble metals and alloys thereof.

19. The method of claim 11 wherein depositing the metal hard mask comprises:
depositing the metal hard mask consisting of at least one of PtMn and IrMn

20. The method of claim 11 wherein depositing the metal hard mask comprises:
depositing the metal hard mask comprising at least one of the elements selected from the group consisting of Pt, Ir, Mo, W, Ru and alloy AB (where A comprises Pt, Ir, Mo, W, Ru and B comprises Fe, Ni, Mn).
